(19) United States
(12) Patent Application Publication
(10) Pub. No.: US 2022/0308431 A1
(43) Pub. Date: Sep. 29, 2022

(54) WAVELENGTH CONVERSION APPARATUS, LIGHT SOURCE APPARATUS, PROJECTOR, AND METHOD FOR MANUFACTURING WAVELENGTH CONVERSION APPARATUS

(71) Applicant: SEIKO EPSON CORPORATION, Tokyo (JP)

(72) Inventor: Satoshi KITO, Chino-shi (JP)

(21) Appl. No.: 17/704,146

(22) Filed: Mar. 25, 2022

(30) Foreign Application Priority Data
Mar. 25, 2021 (JP) 2021-051761

(51) Int. Cl. G03B 21/20; H01L 33/50; H04N 9/31; H01S 5/00; F21K 9/64

(52) U.S. Cl. CPC G03B 21/204; H01L 33/504; H04N 9/3161; H01S 5/0087; G03B 21/2066; F21K 9/64; H01L 33/507

(57) ABSTRACT

A wavelength conversion apparatus according to an aspect of the present disclosure includes a wavelength conversion layer that has a phosphor phase and a matrix phase, the latter of which contains magnesium oxide, and converts excitation light in terms of wavelength and a hydration suppression layer that is provided at least at one of a first surface of the wavelength conversion layer and a second surface on the side opposite from the first surface and suppresses hydration of the magnesium oxide.

The present application is based on, and claims priority from JP Application Ser. No. 2021-051761, filed Mar. 25, 2021, the disclosure of which is hereby incorporated by reference herein in its entirety.

### BACKGROUND

### 1. Technical Field

The present disclosure relates to a wavelength conversion apparatus, a light source apparatus, a projector, and a method for manufacturing the wavelength conversion apparatus.

### 2. Related Art

There has been a proposed light source apparatus using fluorescence emitted from a phosphor when the phosphor is irradiated with excitation light outputted from a light source. JP-A-2012-3923 discloses a light source apparatus that includes a fluorescing member formed of an yttrium-aluminum-garnet-based (YAG-based) phosphor, converts in terms of wavelength part of the excitation light incident via a first surface of the fluorescing member into yellow light, and outputs white light formed of the remaining part of the excitation light and the yellow light via a second surface of the fluorescing member. JP-A-2011-198560 discloses a light source apparatus including a base made of sintered aluminum nitride on which a reflection layer made of barium sulfate and a YAG phosphor layer are sequentially laminated.

In a light source apparatus of this type, when the phosphor is irradiated with the excitation light, the phosphor absorbs the excitation light, resulting in an increase in the temperature of the phosphor. The wavelength conversion efficiency of the phosphor, however, decreases as the temperature of the phosphor increases, and the amount of fluorescence emission decreases accordingly. To avoid the problem described above, it has been known that increasing the thermal conductivity of the phosphor improves the heat dissipation capability of the phosphor. JP-A-2018-180271 discloses a wavelength conversion member containing inorganic phosphor particles and magnesium oxide particles. JP-A-2018-180271 describes that excellent thermal conductivity of the magnesium oxide particles allows the wavelength conversion member to efficiently dissipate the heat generated by the inorganic phosphor particles out of the wavelength conversion member.

The magnesium oxide described above oxide is easily transformed into magnesium hydroxide by moisture in the environmental atmosphere. When the magnesium oxide is transformed into magnesium hydroxide, the thermal conductivity of the wavelength conversion member lowers, so that the wavelength conversion member does not have desired thermal conductivity anymore. As a result, the wavelength conversion efficiency of the wavelength conversion member decreases, so that a desired amount of fluorescence emission may not be provided. Furthermore, simply increasing the amount of excitation light to compensate for the decrease in the wavelength conversion efficiency causes an increase in the temperature of the wavelength conversion member, and it is therefore difficult to compensate for the decrease in the wavelength conversion efficiency.

### SUMMARY

To solve the problem described above, a wavelength conversion apparatus according to an aspect of the present disclosure includes a wavelength conversion layer that has a phosphor phase and a matrix phase, the latter of which contains magnesium oxide, and converts excitation light in terms of wavelength and a hydration suppression layer that is provided at least at one of a first surface of the wavelength conversion layer and a second surface on a side opposite from the first surface and suppresses hydration of the magnesium oxide.

A light source apparatus according to another aspect of the present disclosure includes a light source that outputs the excitation light and the wavelength conversion apparatus according to the aspect of the present disclosure.

A projector according to still another aspect of the present disclosure includes the light source apparatus according to the other aspect of the present disclosure, a light modulator that modulates light outputted from the light source apparatus in accordance with an image signal, and a projection optical apparatus that projects the light modulated by the light modulator.

A method for manufacturing a wavelength conversion apparatus according to still another aspect of the present disclosure includes mixing powder containing a phosphor material and powder containing magnesium oxide with each other to produce mixed powder, sintering the mixed powder into a sintered body, polishing the sintered body to form a wavelength conversion layer, and vaporizing a hydration suppressing material that suppresses hydration of the magnesium oxide and depositing the vaporized hydration suppressing material on at least one of a first surface of the wavelength conversion layer and a second surface on a side opposite from the first surface to form a hydration suppression layer.

### BRIEF DESCRIPTION OF THE DRAWINGS

FIG. 1 is a schematic configuration diagram showing a projector according to a first embodiment.

FIG. 2 is a schematic configuration diagram showing a light source apparatus according to the first embodiment.

FIG. 3 is a cross-sectional view showing a wavelength conversion apparatus according to the first embodiment.

FIG. 4 shows the relationship between a YAG volume ratio and the thermal conductivity of the wavelength conversion layer.

FIG. 5 is a cross-sectional view showing the wavelength conversion apparatus according to a second embodiment.

FIG. 6 is a schematic configuration diagram of the light source apparatus according to a third embodiment.

FIG. 7 is a cross-sectional view of the wavelength conversion apparatus according to the third embodiment.

### DESCRIPTION OF EXEMPLARY EMBODIMENTS

### First Embodiment

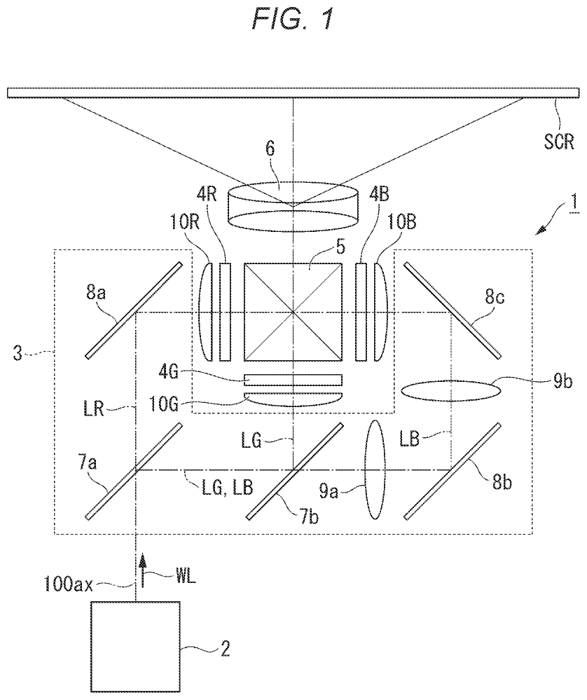

An embodiment of the present disclosure will be described below with reference to FIGS. 1 to 4.

FIG. 1 is a schematic configuration diagram showing a projector according to the first embodiment.

In the following drawings, components are drawn at different dimensional scales in some cases for clarification of each of the components.

A projector 1 according to the present embodiment is a projection-type image display apparatus that displays video images on a screen SCR, as shown in FIG. 1. The projector 1 includes a light source apparatus 2, a color separation system 3, light modulators 4R, 4G, and 4B, a light combining system 5, and a projection optical apparatus 6.

The light source apparatus 2 outputs white illumination light WL toward the color separation system 3. The configuration of the light source apparatus 2 will be described later in detail.

The color separation system 3 separates the illumination light WL outputted from the light source apparatus 2 into red light LR, green light LG, and blue light LB. The color separation system 3 includes a first dichroic mirror 7a, a second dichroic mirror 7b, a first total reflection mirror 8a, a second total reflection mirror 8b, a third total reflection mirror 8c, a first relay lens 9a, and a second relay lens 9b.

The first dichroic mirror 7a separates the illumination light WL from the light source apparatus 2 into the red light LR and light containing the green light LG and the blue light LB. The first dichroic mirror 7a transmits the red light LR and reflects the light containing the green light LG and the blue light LB. On the other hand, the second dichroic mirror 7b reflects the green light LG and transmits the blue light LB. The second dichroic mirror 7b thus separates the light containing the green light LG and the blue light LB into the green light LG and the blue light LB.

The first total reflection mirror 8a is disposed in the optical path of the red light LR and reflects the red light LR having passed through the first dichroic mirror 7a toward the light modulator 4R. On the other hand, the second total reflection mirror 8b and the third total reflection mirror 8c are disposed in the optical path of the blue light LB and guide the blue light LB having passed through the second dichroic mirror 7b to the light modulator 4B. The green light LG is reflected off the second dichroic mirror 7b toward the light modulator 4G.

The first relay lens 9a and the second relay lens 9b are disposed in the optical path of the blue light LB on the light exiting side of the second dichroic mirror 7b. The first relay lens 9a and the second relay lens 9b compensate for optical loss of the blue light LB resulting from the fact that the optical path length of the blue light LB is longer than the optical path lengths of the red light LR and the green light LG.

The light modulator 4R modulates the red light LR in accordance with image information to form image light corresponding to the red light LR. The light modulator 4G modulates the green light LG in accordance with image information to form image light corresponding to the green light LG. The light modulator 4B modulates the blue light LB in accordance with image information to form image light corresponding to the blue light LB.

The light modulators 4R, 4G, and 4B are each, for example, a transmissive liquid crystal panel. Polarizers that are not shown in the figures are disposed on the light incident and exiting sides of each of the liquid crystal panels.

A field lens 10R is disposed on the light incident side of the light modulator 4R. The field lens 10R parallelizes the red light LR to be incident on the light modulator 4R. A field lens 10G is disposed on the light incident side of the light modulator 4G. The field lens 10G parallelizes the green light LG to be incident on the light modulator 4G. A field lens 10B is disposed on the light incident side of the light modulator 4B. The field lens 10B parallelizes the blue light LB to be incident on the light modulator 4B.

The image light outputted from the light modulator 4R, the image light outputted from the light modulator 4G, and the image light outputted from the light modulator 4B enter the light combing system 5. The light combining system 5 combines the image light corresponding to the red light LR, the image light corresponding to the green light LG, and the image light corresponding to the blue light LB with one another and outputs the combined image light toward the projection optical apparatus 6. The light combining system 5 is formed, for example, of a cross dichroic prism.

The projection optical apparatus 6 includes a plurality of projection lenses. The projection optical apparatus 6 enlarges the combined image light from the light combining system 5 and projects the enlarged image light toward the screen SCR. Enlarged video images are thus displayed on the screen SCR.

The configuration of the light source apparatus 2 will be described below.

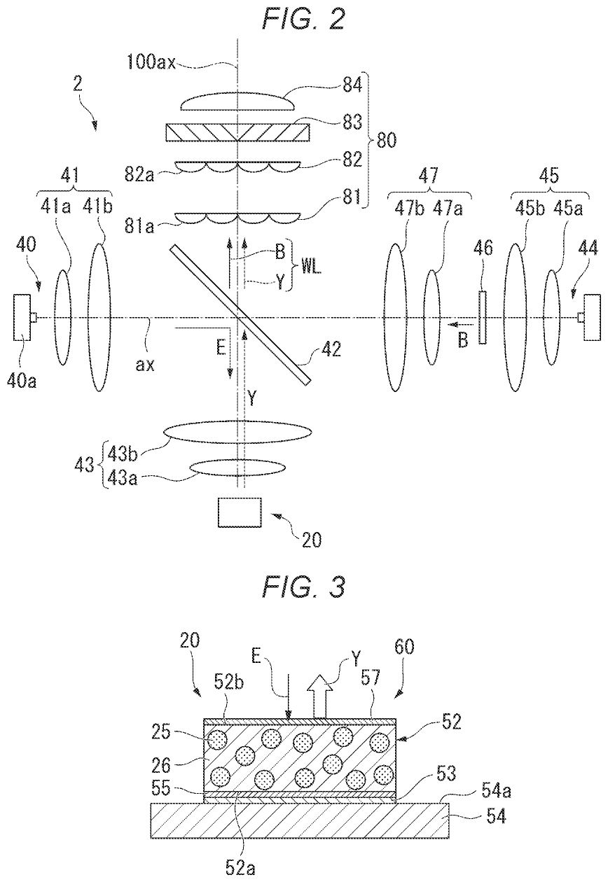

FIG. 2 is a schematic configuration diagram showing the light source apparatus 2 according to the present embodiment.

The light source apparatus 2 includes a first light source 40, a collimation optical system 41, a dichroic mirror 42, a collimation and condenser optical system 43, a wavelength conversion apparatus 20, a second light source 44, a condenser optical system 45, a diffuser 46, and a collimation optical system 47, as shown in FIG. 2.

The first light source 40 is formed of a plurality of semiconductor lasers 40a, which each emit blue excitation light E formed of laser light. The wavelength at which the intensity of the outputted excitation light E peaks, for example, at about 445 nm. The plurality of semiconductor lasers 40a are arranged in an array in a plane perpendicular to an optical axis ax of the first light source 40. A semiconductor laser that outputs blue light having a wavelength other than 445 nm, for example, blue light having a wavelength of 455 nm or 460 nm can instead be used as each of the semiconductor lasers 40a. The optical axis ax of the first light source 40 is perpendicular to an illumination optical axis 100ax of the light source apparatus 2.

The first light source 40 in the present embodiment corresponds to the light source in the claims.

The collimation optical system 41 includes a first lens 41a and a second lens 41b. The collimation optical system 41 substantially parallelizes the light outputted from the first light source 40. The first lens 41a and the second lens 41b are each formed of a convex lens.

The dichroic mirror 42 is disposed in the optical path between the collimation optical system 41 and the collimation and condenser optical system 43 and oriented so as to intersect with the optical axis ax of the first light source 40 and the illumination optical axis 100ax at an angle of 45°. The dichroic mirror 42 reflects a blue light component and transmits a red light component and a green light component. The dichroic mirror 42 therefore reflects the excitation light E and blue light B and transmits yellow fluorescence Y.

The collimation and condenser optical system 43 collects the excitation light E having passed through the dichroic mirror 42 and causes the collected excitation light E to enter the wavelength conversion apparatus 20 and also substantially parallelizes the fluorescence Y emitted from the wavelength conversion apparatus 20. The collimation and condenser optical system 43 includes a first lens 43a and a second lens 43b. The first lens 43a and the second lens 43b are each formed of a convex lens.

The second light source 44 is formed of a semiconductor laser that outputs light having the same wavelength band as that of the light outputted from the first light source 40. The second light source 44 may be formed of one semiconductor laser or a plurality of semiconductor lasers. The second light source 44 may instead be formed of a semiconductor laser that outputs light having a wavelength band different from the wavelength band of the light outputted from the semiconductor lasers of the first light source 40.

The condenser optical system 45 includes a first lens 45a and a second lens 45b. The condenser optical system 45 collects the blue light B outputted from the second light source 44 on or in the vicinity of a diffusion surface of the diffuser 46. The first lens 45a and the second lens 45b are each formed of a convex lens.

The diffuser 46 diffuses the blue light B outputted from the second light source 44 to produce blue light B having a light orientation distribution close to the light orientation distribution of the fluorescence Y emitted from the wavelength conversion apparatus 20. The diffuser 46 can be formed, for example, of a ground glass plate made of optical glass.

The collimation system 47 includes a first lens 47a and a second lens 47b. The collimation system 74 substantially parallelizes the light having exited out of the diffuser 46. The first lens 47a and the second lens 47b are each formed of a convex lens.

The blue light B outputted from the second light source 44 is reflected off the dichroic mirror 42 and combined with the fluorescence Y having been emitted from the wavelength conversion apparatus 20 and having passed through the dichroic mirror 42 into the white illumination light WL. The illumination light WL enters the uniform illumination system 80.

The uniform illumination system 80 includes a first lens array 81, a second lens array 82, a polarization converter 83, and a superimposing lens 84.

The first lens array 81 includes a plurality of first lenses 81a for dividing the illumination light WL from the light source apparatus 2 into a plurality of sub-luminous fluxes. The plurality of first lenses 81a are arranged in a matrix in a plane perpendicular to the illumination optical axis 100ax.

The second lens array 82 includes a plurality of second lenses 82a corresponding to the plurality of first lenses 81a in the first lens array 81. The plurality of second lenses 82a are arranged in a matrix in a plane perpendicular to the illumination optical axis 100ax.

The second lens array 82 along with the superimposing lens 84 brings images of the first lenses 81a in the first lens array 81 into focus in the vicinity of an image formation region of each of the light modulators 4R, 4G, and 4B.

The polarization converter 83 converts the light having exited out of the second lens array 82 into one kind of linearly polarized light. The polarization converter 83 includes, for example, polarization separation films and retardation films (not shown).

The superimposing lens 84 collects the sub-luminous fluxes having exited out of the polarization converter 83 and superimposes the collected sub-luminous fluxes on one another in the vicinity of the image formation region of each of the light modulators 4R, 4G, and 4B.

The configuration of the wavelength conversion apparatus 20 will next be described.

FIG. 3 is a cross-sectional view showing the configuration of the wavelength conversion apparatus 20. FIG. 3 corresponds to the cross section of the wavelength conversion apparatus 20 taken along a plane containing the illumination optical axis 100ax in FIG. 2.

The wavelength conversion apparatus 20 includes a substrate 54, a bonding layer 53, a reflection layer 55, a wavelength conversion layer 52, and a hydration suppression layer 57, as shown in FIG. 3. The reflection layer 55, the wavelength conversion layer 52, and the hydration suppression layer 57 form a wavelength converter 60. The wavelength conversion apparatus 20 according to the present embodiment is formed of a fixed wavelength conversion apparatus in which the position where the excitation light E is incident on the wavelength conversion layer 52 does not change with time.

The substrate 54 supports the wavelength converter 60 including the reflection layer 55, the wavelength conversion layer 52, and the hydration suppression layer 57. The substrate 54 is made of a metal material having high heat conductivity, for example, aluminum or copper.

The bonding layer 53 is provided at a first surface 54a of the substrate 54 and bonds the wavelength converter 60 to the substrate 54. The bonding layer 53 is made of a bonding material having high thermal conductivity, for example, nano-silver paste.

The reflection layer 55 is provided so as to face the first surface 54a of the substrate 54 with the bonding layer 53 therebetween. That is, the reflection layer 55 is provided between the substrate 54 and a first surface 52a of the wavelength conversion layer 52. The reflection layer 55 is formed of a film made of metal having high optical reflectance, such as silver, a dielectric multilayer film, or a combination thereof.

The wavelength conversion layer 52 has the first surface 52a, which faces the reflection layer 55, and a second surface 52b on the side opposite from the first surface 52a. In the wavelength conversion layer 52, the excitation light E incident via the second surface 52b is converted in terms of wavelength into the fluorescence Y, which exits via the second surface 52b. That is, the wavelength converter 60 in the present embodiment is a reflective wavelength converter.

The wavelength conversion layer 52 has a phosphor phase 25 and a matrix phase 26, the latter of which contains magnesium oxide (MgO). The phosphor phase 25 contains an oxide phosphor to which an activator has been added. The phosphor phase 25 is formed of a plurality of phosphor particles. The phosphor phase 25 contains, for example, yttrium aluminum garnet (YAG (Y₃Al₅O₁₂): Ce) to which cerium (Ce) has been added as the activator.

Consider YAG:Ce by way of example, and the phosphor particles can be made, for example, of a material produced by mixing raw powder materials containing Y₂O₃, Al₂O₃, CeO₃, and other constituent elements with one another and causes the mixture to undergo a solid-phase reaction, Y—Al—O amorphous particles produced by using a coprecipitation method, a sol-gel method, or any other wet method, or YAG particles produced by using a spray-drying method, a flame-based thermal decomposition method, a thermal plasma method, or any other gas-phase method.

The oxide phosphor that forms the phosphor phase 25 may include at least one of Y₃(Al, Ga)₅O₁₂, Lu₃Al₅O₂, and TbAl₅O₁₂ in addition to Y₃Al₅O₁₂. The phosphor phase 25 may contain europium (Eu) in place of cerium (Ce) as the activator.

The matrix phase 26 functions as a binder that binds the plurality of phosphor particles that form the phosphor phase 25 together. The matrix phase 26 is made of a material containing magnesium oxide as a light transmissive ceramic material. The thermal conductivity of the magnesium oxide that forms the matrix phase 26 is about 50 W/m·K. The thermal conductivity of the YAG that forms the phosphor phase 25 is about 9 W/m·K. That is, the light transmissive ceramic material contained in the matrix phase 26 has thermal conductivity higher than that of the phosphor phase 25.

The metal oxide that forms the matrix phase 26 may contain at least one of Al₂O₃, ZnO, TiO₂, Y₂O₃, YAlO₃, BeO, and MgAl₂O₄ in addition to MgO described above. The thermal conductivity of Al₂O₃ is about 30 W/m·K. The thermal conductivity of ZnO is about 25 W/m·K. The thermal conductivity of TiO₂ is about 43 W/m·K. The thermal conductivity of Y₂O₃ is about 27 W/m·K. The thermal conductivity of YAlO₃ is about 12 W/m·K. The thermal conductivity of BeO is about 250 W/m·K. The thermal conductivity of MgAl₂O₄ is about 14 W/m·K.

In the wavelength conversion layer 52 in the present embodiment, the content of the phosphor phase 25 is, for example, about 20 vol % by volume of the entire phase including the matrix phase 26 and the phosphor phase 25. In the following present specification, the volume ratio of the phosphor phase 25 to the entire phase, which is the combination of the matrix phase 26 and the phosphor phase 25, is referred to as a YAG volume ratio.

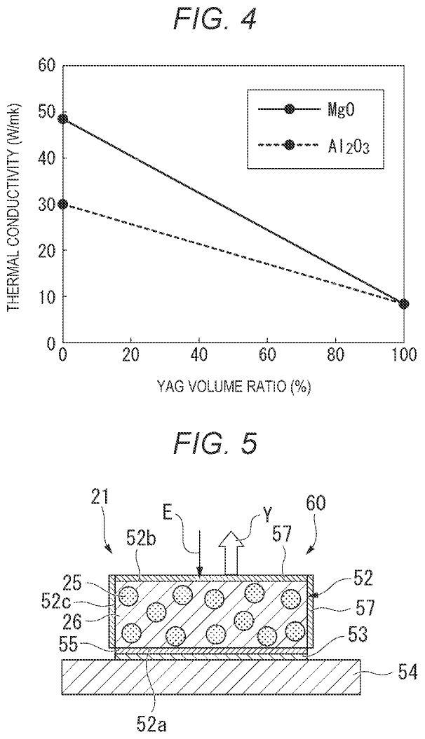

FIG. 4 shows the relationship between the YAG volume ratio and the thermal conductivity of the wavelength conversion layer 52.

In FIG. 4, the horizontal axis represents the YAG volume ratio (vol %), and the vertical axis represents the thermal conductivity (W/m·K). The solid-line graph represents the present embodiment in which MgO is used as the matrix phase. The broken-line graph represents Comparative Example in which Al₂O₃ is used as the matrix phase. The thermal conductivity is expressed by values at room temperature.

The thermal conductivity linearly decreases as the YAG volume ratio increases in both the present embodiment and Comparative Example, as shown in FIG. 4. Comparison at any single YAG volume ratio shows that the thermal conductivity of the wavelength conversion layer 52 in the present embodiment, in which MgO is used as the matrix phase, is higher than the thermal conductivity of the wavelength conversion layer in Comparative Example, in which Al₂O₂ is used as the matrix phase. In the present embodiment, in which a target value of the thermal conductivity is assumed to be about 40 W/m·K, the YAG volume ratio is desirably about 20 vol %.

The hydration suppression layer 57 is provided at the second surface 52b of the wavelength conversion layer 52, as shown in FIG. 3. The hydration suppression layer 57 is made of a material containing, for example, one or more of silicon dioxide (SiO₂), titanium trioxide (TiO₃), magnesium difluoride (MgF₂), niobium pentoxide (Nb₂O₅), and tantalum pentoxide (Ta₂O₅). The hydration suppression layer 57 made of any of the materials described above suppresses hydration of the magnesium oxide that forms the matrix phase 26 of the wavelength conversion layer 52. The hydration suppression layer 57 transmits the excitation light E to cause it to enter the wavelength conversion layer 52 and transmits the fluorescence Y generated in the wavelength conversion layer 52 to cause it to exit out thereof.

A method for manufacturing the wavelength conversion apparatus 20 according to the present embodiment will be described below.

First, predetermined amounts of Al₂O₃powder, Y₂O₃ powder, and CeO₂ powder, which are raw material powder of YAG:Ce, are mixed with a predetermined amount of ethanol, and ball milling is performed on the mixture in a pot to produce slurry. The slurry is dried, granulated, then degreased, and sintered to produce YAG:Ce powder. The YAG:Ce powder is hereinafter abbreviated to YAG powder. Prepare MgO powder separately.

The YAG powder is then mixed with the MgO powder to produce mixed powder. In this process, for example, the YAG powder and the MgO powder are put into an ethanol solvent, and then the solvent is volatilized and dried to produce mixed powder in which the YAG powder and the MgO powder are uniformly mixed with each other.

The mixed powder of YAG and MgO produced in the previous step is then sintered into a sintered body. The sintering is performed by using hot pressing at a temperature lower than or equal to the temperature at which YAG reacts with magnesium oxide, for example, at 1000° C. to prevent the YAG and MgO from reacting with each other. Using hot pressing allows densification of the sintered body. Hot pressing is not necessarily used, for example, atmospheric firing may be used.

The sintered body produced in the previous step is then polished into the wavelength conversion layer 52.

The hydration suppression layer 57 is then formed by vaporizing a hydration suppressing material, such as SiO₂, TiO₃, MgF₂, Nb₂O₅, and Ta₂O₅, and depositing the vaporized hydration suppressing material on one surface of the wavelength conversion layer 52 produced in the previous step. Since the thickness of the wavelength conversion layer 52 is about a few tens of micrometers, the hydration suppressing material may not to be deposited on the side surfaces of the wavelength conversion layer 52.

The wavelength conversion apparatus 20 in the present embodiment is completed by carrying out the steps described above.

When a large number of pores are present in the surface of the wavelength conversion layer 52, the hydration suppressing material may not continuously form a film, so that a defective hydration suppression layer 57 may be formed. In this case, a coating agent, for example, polysilazane may be applied onto the surface of the wavelength conversion layer 52 to fill the pores before the hydration suppressing material is vaporized and deposited, and the hydration suppressing material may then vaporized and deposited. A hydration suppression layer 57 with few defects can thus be formed.

### Effects of First Embodiment

As described above, the wavelength conversion apparatus 20 according to the present embodiment includes the wavelength conversion layer 52, which has the phosphor phase 25 and the matrix phase 26, the latter of which contains magnesium oxide, and converts the excitation light E in terms of wavelength, and the hydration suppression layer 57, which is provided at the second surface 52b of the wavelength conversion layer 52 and suppresses hydration of the magnesium oxide.

According to the configuration described above, since the matrix phase, which forms the wavelength conversion layer 52, contains magnesium oxide having high thermal conductivity, the thermal conductivity of the wavelength conversion layer 52 as a whole is improved, whereby the heat generated in the wavelength conversion layer 52 can be efficiently transferred to the substrate 54 via the reflection layer 55 and the bonding layer 53. The wavelength conversion apparatus 20 can thus suppress a decrease in wavelength conversion efficiency caused due to an increase in temperature of the wavelength conversion layer 52.

However, magnesium oxide excels in thermal conductivity but is readily hydrated and transformed into magnesium hydroxide by moisture in the environmental atmosphere. When the magnesium oxide is transformed into magnesium hydroxide, the thermal conductivity thereof lowers, so that the transformed magnesium hydroxide does not have desired thermal conductivity anymore. Therefore, when the wavelength conversion apparatus 20 is used for a long period, the wavelength conversion efficiency of the wavelength conversion layer 52 may lower, so that a desired amount of fluorescence emission may not be provided. To solve the problem, in the wavelength conversion apparatus 20 according to the present embodiment, the hydration suppression layer 57 is provided at the second surface 52b of the wavelength conversion layer 52, which is the surface exposed to the environmental atmosphere, whereby the transformation of the magnesium oxide into magnesium hydroxide can be suppressed, and desired thermal conductivity of the magnesium oxide can be ensured. The wavelength conversion efficiency of the wavelength conversion layer 52 can thus be maintained over a long period of use.

In the wavelength conversion apparatus 20 according to the present embodiment, the hydration suppression layer 57 is made of a material containing, for example, one or more of silicon dioxide (SiO₂), titanium trioxide (TiO₃), magnesium difluoride (MgF₂), niobium pentoxide (Nb₂O₅), and tantalum pentoxide (Ta₂O₅).

According to the configuration described above, the hydration suppression layer 57, which suppresses the hydration of the magnesium oxide, can provide the desired effect.

The wavelength conversion apparatus 20 according to the present embodiment further includes the substrate 54 and the reflective layer 55 provided between the substrate 54 and the first surface 52a of the wavelength conversion layer 52. The hydration suppression layer 57 is provided at the second surface 52b of the wavelength conversion layer 52, transmits the excitation light E to cause it to enter the wavelength conversion layer 52 and transmits the fluorescence Y generated in the wavelength conversion layer 52 to cause it to exit out thereof.

According to the configuration described above, a reflective wavelength conversion apparatus 20 can be configured and used as a fixed wavelength conversion apparatus in the present embodiment. The reflective wavelength conversion apparatus 20 can also be used as a rotating wavelength conversion apparatus.

The light source apparatus 20 according to the present embodiment includes the first light source 40, which outputs the excitation light E, and the wavelength conversion apparatus 20.

The configuration described above allows the light source apparatus 2 to excel in the wavelength conversion efficiency.

The projector 1 according to the present embodiment includes the light source apparatus 2, the light modulators 4R, 4G, and 4B, which modulate the light outputted from the light source apparatus 2 in accordance with image signals, and the projection optical apparatus 6, which projects the light modulated by the light modulators 4R, 4G, and 4B.

The configuration described above allows the projector 1 to excel in display quality and to be highly efficient.

The method for manufacturing the wavelength conversion apparatus 20 according to the present embodiment includes mixing powder made of a phosphor material and magnesium oxide powder with each other to produce mixed powder, sintering the mixed powder into a sintered body, polishing the sintered body to form the wavelength conversion layer 52, and vaporizing a hydration suppressing material that suppresses hydration of the magnesium oxide to form the hydration suppression layer 57 and depositing the vaporized material on the second surface 52b of the wavelength conversion layer 52.

According to the manufacturing method described above, the wavelength conversion apparatus 20 can be manufactured so as to maintain high wavelength conversion efficiency over a long period of use.

In the present embodiment, in the step of forming the sintered body, the mixed powder is sintered by using hot pressing at a temperature lower than or equal to the temperature at which the phosphor material reacts with the magnesium oxide.

According to the method described above, the function of each of the phosphor material and the magnesium oxide is maintained, and the effect of suppressing the decrease in the wavelength conversion efficiency can be ensured.

### Second Embodiment

A second embodiment of the present disclosure will be described below with reference to FIG. 5.

The basic configuration of the wavelength conversion apparatus according to the second embodiment is the same as that in the first embodiment, but the configuration of the hydration suppression layer differs from that in the first embodiment. The basic configuration of the wavelength converter will not therefore be described.

FIG. 5 is a cross-sectional view showing a wavelength conversion apparatus 21 according to the second embodiment.

In FIG. 5, components common to those in the first embodiment have the same reference characters and will not be described.

The wavelength conversion apparatus 21 includes the substrate 54, the bonding layer 53, the reflection layer 55, the wavelength conversion layer 52, and the hydration suppression layer 57, as shown in FIG. 5.

The wavelength conversion layer 52 has the first surface 52a, the second surface 52b, and a side surface 52c extending along the direction that intersects the first surface 52a and the second surface 52b. In FIG. 5, the side surface 52c is shown as a flat surface but may instead, for example, be a curved surface, or the corner between the side surface 52c and the first surface 52a or the corner between the side surface 52c and the second surface 52b may be chamfered.

In the present embodiment, the hydration suppression layer 57 is also provided at the side surface 52c in addition to the hydration suppression layer 57 provided as the second surface 52b of the wavelength conversion layer 52. The other configurations of the wavelength conversion apparatus 21 are the same as those of the wavelength conversion apparatus 20 according to the first embodiment.

### Effects of Second Embodiment

The present embodiment also provides the same effects as those provided by the first embodiment, such as the capability of maintaining over a long period of time the effect of suppressing the decrease in the wavelength conversion efficiency due to an increase in the temperature of the wavelength conversion layer 52.

Furthermore, in the wavelength conversion apparatus 21 according to the present embodiment, since the hydration suppression layer 57 is also provided at the side surface 52c of the wavelength conversion layer 52, the transformation of the magnesium oxide produced by a small amount via the side surface 52c of the wavelength conversion layer 52 can also be reliably suppressed.

### Third Embodiment

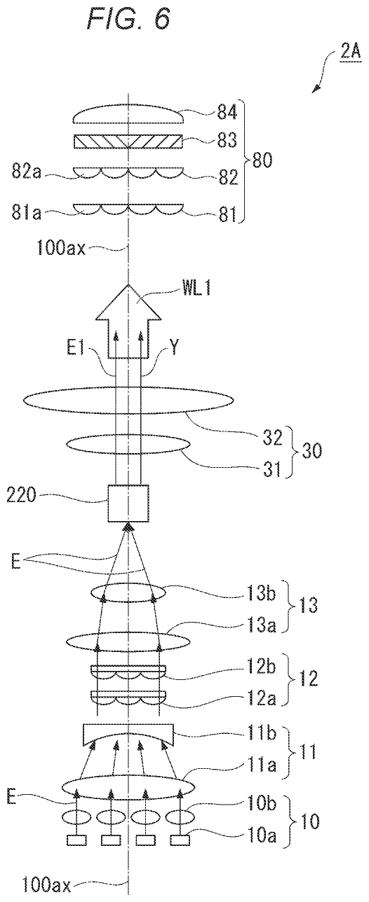

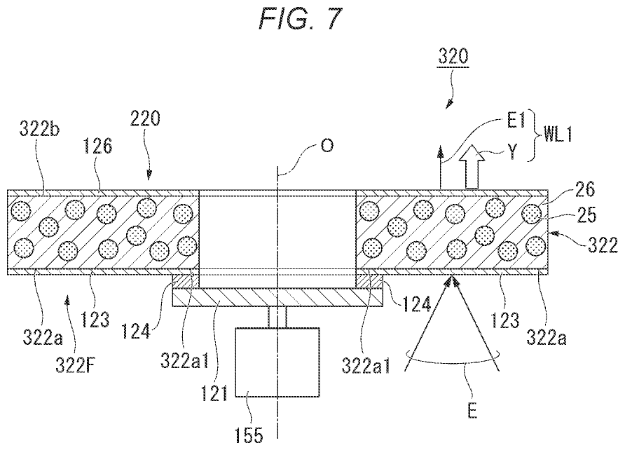

A third embodiment of the present disclosure will be described below with reference to FIGS. 6 and 7.

The basic configuration of the projector according to the third embodiment is the same as that in the first embodiment, but the configurations of the light source apparatus and the wavelength conversion apparatus differ from those in the first embodiment. The configurations of the light source apparatus and the wavelength conversion apparatus will therefore be described below.

FIG. 6 is a schematic configuration diagram of a light source apparatus 2A according to the third embodiment. FIG. 7 is a cross-sectional view of a wavelength conversion apparatus 320 according to the third embodiment.

In FIGS. 6 and 7, components common to those in the figures used in the embodiments described above have the same reference characters and will not be described.

The light source apparatus 2A includes an excitation light source unit 10, an afocal optical system 11, a homogenizer optical system 12, a condenser optical system 13, a wavelength converter 220, a pickup optical system 30, and the uniform illumination optical system 80, as shown in FIG. 6.

The excitation light source 10 is formed of a plurality of semiconductor lasers 10a, which each output the blue excitation light E formed of laser light, and a plurality of collimator lenses 10b. The plurality of semiconductor lasers 10a are arranged in an array in a plane perpendicular to the illumination optical axis 100ax. The collimator lenses 10b are arranged in an array in a plane perpendicular to the illumination optical axis 100ax in correspondence with the semiconductor lasers 10a. The collimator lenses 10b each convert the excitation light E outputted from the semiconductor laser 10a corresponding to the collimator lens 10b into parallelized light.

The excitation light source unit 10 in the present embodiment corresponds to the light source in the claims.

The afocal optical system 11 includes, for example, a convex lens 11a and a concave lens 11b. The afocal optical system 11 reduces the luminous flux diameter of the excitation light E, which is formed of the parallelized luminous flux outputted from the excitation light source unit 10.

The homogenizer optical system 12 includes, for example, a first multi-lens array 12a and a second multi-lens array 12b. The homogenizer optical system 12 achieves a uniform optical intensity distribution of the excitation light on the wavelength converter 220 or what is called a top-hat distribution. The homogenizer optical system 12 superimposes, along with the condenser optical system 13, a plurality of thin luminous fluxes having exited out of a plurality of lenses of the first multi-lens array 12a and the second multi-lens array 12b on one another on the wavelength converter 220. The optical intensity distribution of the excitation light E radiated onto the wavelength converter 220 is thus made uniform.

The condenser optical system 13 includes, for example, a first lens 13a and a second lens 13b. In the present embodiment, the first lens 13a and the second lens 13b are each formed of a convex lens. The condenser optical system 13 is disposed in the optical path from the homogenizer optical system 12 to the wavelength converter 220, collects the excitation light E, and causes the collected excitation light E to enter the wavelength converter 220. The configuration of the wavelength converter 220 will be described later.

The pickup optical system 30 includes, for example, a first collimation lens 31 and a second collimation lens 32. The pickup optical system 30 is a parallelizing optical system that substantially parallelizes the light having exited out of the wavelength converter 220. The first collimation lens 31 and the second collimation lens 32 are each formed of a convex lens. The light parallelized by the pickup optical system 30 enters the uniform illumination optical system 80.

The wavelength conversion apparatus 320 includes a substrate 121, a wavelength conversion layer 322, a first hydration suppression layer 123, a second hydration suppression layer 126, a bonding layer 124, and a motor 155, as shown in FIG. 7. The wavelength conversion layer 322, the first hydration suppression layer 123, and the second hydration suppression layer 126 form the wavelength converter 220. The wavelength conversion apparatus 320 according to the present embodiment is formed of a rotating wheel type wavelength conversion apparatus in which the position where the excitation light E is incident on the wavelength converter 220 changes with time.

The substrate 121 is a disc-shaped, non-light-transmissive member. The substrate 121 is made of a metal material that excels in heat dissipation, for example, aluminum or copper. The substrate 121 is rotatable around a predetermined axis of rotation O. The axis of rotation O passes through the center of the substrate 121. The motor 155 rotates the substrate 121 around the axis of rotation O.

The wavelength conversion layer 322 has an annular shape around the axis of rotation O. The wavelength conversion layer 322 has the phosphor phase 25 and the matrix phase 26, the latter of which contains magnesium oxide (MgO), as the wavelength conversion layer 52 in the first embodiment does. The wavelength conversion layer 322 contains magnesium oxide in the form of the matrix phase 26 and has high thermal conductivity of, for example, about 40 W/m·K.

The wavelength conversion layer 322 has a first surface 322a and a second surface 322b on the side opposite from the first surface 322a. The first surface 322a faces the condenser optical system 13 (see FIG. 6), and the second surface 322b faces the pickup optical system 30 (see FIG. 6). The wavelength converter 220 in the present embodiment is a transmissive wavelength conversion element that causes the excitation light E to enter the wavelength conversion layer 322 via the first surface 322a and outputs the fluorescence Y from the wavelength conversion layer 322 via the second surface 322b.

The wavelength conversion layer 322, specifically, a radially inner end portion 322a1 of the first surface 322a is fixed to the substrate 121 via the bonding layer 124. The bonding layer 124 is made of a bonding material having high thermal conductivity, for example, nano-silver paste, as the bonding layer 53 in the first embodiment is. In the plan view in the direction along the axis of rotation O, the wavelength conversion layer 322 includes an exposed section 322F, which protrudes radially outward beyond the substrate 121 and is exposed to the external atmosphere. The excitation light E is therefore incident on the exposed section 322F of the wavelength conversion layer 322. A region of the wavelength conversion layer 322 that is the region extending radially inward from the exposed section 322F is in contact with the substrate 121 via the bonding layer 124. The heat generated in the wavelength conversion layer 322 thus propagates to the substrate 121 via the bonding layer 124.

The first hydration suppression layer 123 is provided at the first surface 322a of the wavelength conversion layer 322. In the present embodiment, the first hydration suppression layer 123 is provided across the entire first surface 322a of the wavelength conversion layer 322, and the first hydration suppression layer 123 does not need to be provided in the region in contact with the bonding layer 124 and only needs to be provided at least in the exposed region 322F. The first hydration suppression layer 123 transmits the excitation light E and causes it to enter the wavelength conversion layer 322.

The second hydration suppression layer 126 is provided at the second surface 322b of the wavelength conversion layer 322. The second hydration suppression layer 126 transmits the fluorescence Y produced by the wavelength conversion layer 322 to cause it to exit out thereof. In the present embodiment, the second hydration suppression layer 126 transmits, in addition to the fluorescence Y, a portion of the excitation light E1 that is the portion not having been converted in terms of wavelength by the wavelength conversion layer 322 to cause them to exit out thereof. White illumination light WL1 thus exits out of the wavelength conversion layer 322. In the present embodiment, both the first hydration suppression layer 123 and the second hydration suppression layer 126 are provided, and either one of the first hydration suppression layer 123 or the second hydration suppression layer 126 may be provided. Also in the present embodiment, a hydration suppression layer may be further provided at the side surface of the wavelength conversion layer 322.

The hydration suppression layer 123 and the second hydration suppression layer 126 are each made of a material containing, for example, one or more of silicon dioxide (SiO₂), titanium trioxide (TiO₃), magnesium difluoride (MgF₂), niobium pentoxide (Nb₂O₅), and tantalum pentoxide (Ta₂O₅). The first hydration suppression layer 123 and the second hydration suppression layer 126 may be made of the same material or materials different from each other.

In addition to suppressing the hydration of the magnesium oxide, the first hydration suppression layer 123 may function as a dichroic film so as to transmit the excitation light and reflect the fluorescence. The characteristic described above can be achieved by appropriate selection of the material and thickness of the hydration suppression layer.

### Effects of Third Embodiment

The present embodiment also provides the same effects as those provided by the first embodiment, such as the capability of maintaining over a long period of time the effect of suppressing the decrease in the wavelength conversion efficiency due to an increase in the temperature of the wavelength conversion layer 322.

The wavelength conversion apparatus 320 according to the present embodiment includes the substrate 121, at which the wavelength conversion layer 322 is provided, and the wavelength conversion layer 322 includes the exposed section 322F exposing beyond the substrate 121. The hydration suppression layers 123 and 126 are provided at least at the first surface 322a and the second surface 322b of the exposed section 322F of the wavelength conversion layer 322. The first hydration suppression layer 123 provided at the first surface 322a transmits the excitation light E to cause it to enter the wavelength conversion layer 322, and the second hydration suppression layer 126 provided at the second surface 322b transmits the fluorescence Y generated in the wavelength conversion layer 322 and cause it to exit out thereof.

According to the configuration described above, the hydration of the magnesium oxide can be reliably suppressed even in the case of the wavelength conversion layer 322 including the exposed section 322F, which tends to be exposed to the external atmosphere, whereby the transmissive wavelength conversion apparatus 320 can be configured to excel in the wavelength conversion efficiency.

In the wavelength conversion apparatus 320 according to the present embodiment, in which the wavelength conversion layer 322 is rotated, the position where the excitation light E is incident on the wavelength conversion layer 322 is moved with time. The configuration described above prevents only part of the wavelength conversion layer 322 from being locally heated, whereby degradation of the wavelength conversion layer 322 is avoided. As described above, in the present embodiment, in addition to the configuration in which the wavelength conversion layer 322 has the matrix phase 26 formed of MgO having high thermal conductivity, the heat dissipation capability of the wavelength conversion layer 322 can be further improved by rotating the wavelength conversion layer 322.

The technical scope of the present disclosure is not limited to the embodiments described above, and a variety of changes can be made thereto to the extent that the changes do not depart from the substance of the present disclosure.

The specific descriptions of the shape, the number, the arrangement, the material, the manufacturing method, and other factors of the components of the wavelength conversion apparatus, the light source apparatus, and the projector presented in the embodiments described above are not limited to those in the embodiments described above and can be changed as appropriate.

The above embodiments have been described with reference to the case where the light source apparatus according to the present disclosure is incorporated in a projector using liquid crystal light valves, but not necessarily. A light source apparatus according to an aspect of the present disclosure may be incorporated, for example, in a projector using a digital micromirror device as each of the light modulators.

The above embodiments have been described with reference to the case where the light source apparatus according to the present disclosure is incorporated in a projector, but not necessarily. The light source apparatus according to the present disclosure may be used as a lighting apparatus, a headlight of an automobile, and other components.

A wavelength conversion apparatus according to an aspect of the present disclosure may have the configuration below.

The wavelength conversion apparatus according to the aspect of the present disclosure includes a wavelength conversion layer that has a phosphor phase and a matrix phase, the latter of which contains magnesium oxide, and converts excitation light in terms of wavelength, and a hydration suppression layer that is provided at least at one of a first surface of the wavelength conversion layer and a second surface on the side opposite from the first surface and suppresses hydration of the magnesium oxide.

In the wavelength conversion apparatus according to the aspect of the present disclosure, the hydration suppression layer may be made of a material containing one or more of silicon dioxide (SiO₂), titanium trioxide (TiO₃), magnesium difluoride (MgF₂), niobium pentoxide (Nb₂O₅), and tantalum pentoxide (Ta₂O₅).

The wavelength conversion apparatus according to the aspect of the present disclosure may further include a substrate and a reflection layer provided between the substrate and the first surface of the wavelength conversion layer, and the hydration suppression layer may be provided at the second surface of the wavelength conversion layer, may transmit the excitation light to cause the excitation light to enter the wavelength conversion layer, and may transmit fluorescence generated in the wavelength conversion layer to cause the fluorescence to exit out thereof.

The wavelength conversion apparatus according to the aspect of the present disclosure may further include a substrate at which the wavelength conversion layer is provided. The wavelength conversion layer may include an exposed section exposing beyond the substrate. The hydration suppression layer may be provided at least at the first and second surfaces of the exposed section of the wavelength conversion layer. The hydration suppression layer provided at the first surface may transmit the excitation light to cause the excitation light to enter the wavelength conversion layer, and the hydration suppression layer provided at the second surface may transmit fluorescence generated in the wavelength conversion layer to cause the fluorescence to exit out thereof.

In the wavelength conversion apparatus according to the aspect of the present disclosure, the wavelength conversion layer may have a side surface extending along a direction that intersects with the first and second surfaces, and the hydration suppression layer may be further provided at the side surface.

A light source apparatus according to another aspect of the present disclosure includes a light source that outputs the excitation light and the wavelength conversion apparatus according to the aspect of the present disclosure.

A projector according to still another aspect of the present disclosure includes the light source apparatus according to the other aspect of the present disclosure, a light modulator that modulates light outputted from the light source apparatus in accordance with an image signal, and a projection optical apparatus that projects the light modulated by the light modulator.

A method for manufacturing a wavelength conversion apparatus according to still another aspect of the present disclosure includes mixing powder containing a phosphor material and powder containing magnesium oxide with each other to produce mixed powder, sintering the mixed powder into a sintered body, polishing the sintered body to form a wavelength conversion layer, and vaporizing a hydration suppressing material that suppresses hydration of the magnesium oxide and depositing the vaporized hydration suppressing material on at least one of a first surface of the wavelength conversion layer and a second surface on the side opposite from the first surface to form a hydration suppression layer.

In the method for manufacturing a wavelength conversion apparatus according to the still other aspect of the present disclosure, in the formation of a sintered body, the mixed powder may be sintered by using hot pressing at a temperature lower than or equal to the temperature at which the phosphor material reacts with the magnesium oxide.

What is claimed is:

1. A wavelength conversion apparatus comprising:
a wavelength conversion layer that has a phosphor phase and a matrix phase, the latter of which contains magnesium oxide, and converts excitation light in terms of wavelength; and
a hydration suppression layer that is provided at least at one of a first surface of the wavelength conversion layer and a second surface on a side opposite from the first surface and suppresses hydration of the magnesium oxide.

2. The wavelength conversion apparatus according to claim 1, wherein the hydration suppression layer is made of a material containing one or more of silicon dioxide (SiO₂), titanium trioxide (TiO₃), magnesium difluoride (MgF₂), niobium pentoxide (Nb₂O₅), and tantalum pentoxide (Ta₂O₃).

3. The wavelength conversion apparatus according to claim 1, further comprising:
a substrate; and
a reflection layer provided between the substrate and the first surface of the wavelength conversion layer,
wherein the hydration suppression layer is provided at the second surface of the wavelength conversion layer, transmits the excitation light to cause the excitation light to enter the wavelength conversion layer, and transmits fluorescence generated in the wavelength conversion layer to cause the fluorescence to exit out thereof.

4. The wavelength conversion apparatus according to claim 3,
wherein the wavelength conversion layer has a side surface extending along a direction that intersects with the first and second surfaces, and
the hydration suppression layer is further provided at the side surface.

5. A light source apparatus comprising:
a light source that outputs the excitation light; and
the wavelength conversion apparatus according to claim 3.

6. A projector comprising:
the light source apparatus according to claim 5;
a light modulator that modulates light outputted from the light source apparatus in accordance with an image signal; and
a projection optical apparatus that projects the light modulated by the light modulator.

7. The wavelength conversion apparatus according to claim 1,
further comprising a substrate at which the wavelength conversion layer is provided,
wherein the wavelength conversion layer includes an exposed section exposing beyond the substrate,
the hydration suppression layer is provided at least at the first and second surfaces of the exposed section of the wavelength conversion layer,
the hydration suppression layer provided at the first surface transmits the excitation light to cause the excitation light to enter the wavelength conversion layer, and
the hydration suppression layer provided at the second surface transmits fluorescence generated in the wavelength conversion layer to cause the fluorescence to exit out thereof.

8. The wavelength conversion apparatus according to claim 7, wherein the hydration suppression layer provided at the first surface transmits the excitation light and reflects the fluorescence.

9. In the wavelength conversion apparatus according to claim 7,
wherein the wavelength conversion layer has a side surface extending along a direction that intersects with the first and second surfaces, and
the hydration suppression layer is further provided at the side surface.

10. A light source apparatus comprising:
a light source that outputs the excitation light; and
the wavelength conversion apparatus according to claim 7.

11. A projector comprising:
the light source apparatus according to claim 10;
a light modulator that modulates light outputted from the light source apparatus in accordance with an image signal; and
a projection optical apparatus that projects the light modulated by the light modulator.

12. A method for manufacturing a wavelength conversion apparatus, the method comprising:
mixing powder containing a phosphor material and powder containing magnesium oxide with each other to produce mixed powder;
sintering the mixed powder into a sintered body;
polishing the sintered body to form a wavelength conversion layer; and
vaporizing a hydration suppressing material that suppresses hydration of the magnesium oxide and depositing the vaporized hydration suppressing material on at least one of a first surface of the wavelength conversion layer and a second surface on a side opposite from the first surface to form a hydration suppression layer.

13. The method for manufacturing a wavelength conversion apparatus according to claim 12, wherein in the formation of a sintered body, the mixed powder is sintered by using hot pressing at a temperature lower than or equal to a temperature at which the phosphor material reacts with the magnesium oxide.
